(19) United States
(12) Patent Application Publication
(10) Pub. No.: US 2017/0138996 A1
(43) Pub. Date: May 18, 2017

(54) DIFFERENTIAL PROTECTION METHOD AND DIFFERENTIAL PROTECTION DEVICE

(71) Applicant: SIEMENS AKTIENGESELLSCHAFT, MUENCHEN (DE)

(72) Inventors: WALDEMAR REBIZANT, WROCLAW (PL); LUDWIG SCHIEL, BERLIN (DE); ANDRZEJ WISZNIEWSKI, WROCLAW (PL)

(21) Appl. No.: 15/129,920

(22) PCT Filed: Mar. 28, 2014
(86) PCT No.: PCT/EP2014/056284

§ 371 Date: Sep. 28, 2016

(51) Int. Cl. G01R 31/02; G01R 31/40

(52) U.S. Cl. CPC G01R 31/025; G01R 31/40

(57) ABSTRACT

A differential protection method generates a fault signal which indicates that a fault has occurred at an electrical component of an energy supply network. Differential current values and stabilization values are formed from current measurement values at different measurement points of the component and the fault signal is generated if a measured value pair, formed from one of the differential current values and the respectively associated stabilization value, lies in a predetermined tripping range. The stabilization current values in a predetermined observation period are compared with the respective associated differential current values and, based on the comparison, a fault indicator is formed, which indicates whether the proportion of the differential current values or the proportion of the stabilization current values is greater. The generation of the fault signal is blocked if the fault indicator indicates a greater proportion of the stabilization current values.

The present invention relates to a differential protection method for generating a fault signal which indicates a fault occurring in the area of an electrical component of an electrical power supply system, in which current measurement values are measured at each of at least two different measurement locations of the component, and differential current values and stabilization values are formed via the current measurement values, and the fault signal is generated if it is determined within the scope of a triggering range test that a measurement value pair formed from one of the differential current values and the associated stabilization value in each case lies in a predefined triggering range. The present invention also relates to a differential protection device including a measurement value detection device for detecting current measurement values determined at different locations of an electrical component of an electrical power supply system, and including an analysis device which is configured for the formation of differential current values and stabilization values from the current measurement values and for generating a fault signal, if it is determined within the scope of a triggering range test that a measurement value pair formed from one of the differential current values and the associated stabilization value in each case lies in a predefined triggering range.

Such a differential protection method and such a differential protection device are, for example, known from the product manual of the differential protection device SIPROTEC 7UT6x “SIPROTEC—Differential Protection 7UT6x, V4.6, Siemens AG 2013, Order Number C53000-1176-C230-3”. In the case of the known differential protection device, current measurement values are detected at two measurement locations of an electrical component, for example, on the high-voltage side and the low-voltage side of a transformer, and differential current values and stabilization current values are ascertained from them. Based on the location of the measurement value pair formed from a differential current value and an associated stabilization current value in a diagram, the existence of a fault, for example, a short circuit, is deduced and a corresponding fault signal is generated. In the case of the existence of a fault signal, a switch is ultimately triggered to open its switching contacts in order to disconnect the faulty component from the electrical power supply system.

In addition, in the case of the differential protection for transformers, it is known to stabilize the described differential protection function via further additional algorithms for increasing the reliability of decisions about the existence of a fault in the area of an electrical component. These additional algorithms are used for detecting certain operating states of the electrical power supply system and blocking the generation of the fault signal in the case of detection of such an operating state. In this way, it is achieved that the fault signal is generated reliably only in the case of the actual existence of a fault. The aforementioned operating states of the electrical power supply system may, for example, include activation operations in the electrical power supply system, the occurrence of certain harmonic oscillations with respect to current and/or voltage in the electrical power supply system, the existence of external faults of particularly high current intensity (i.e., faults which lie outside the range of the monitored component, but which demonstrate behavior similar to that of internal faults in some cases), or the occurrence of transformer saturation. For example, from WO 2010/034635 A1, a method is known via which an activation operation in an electrical power supply system is detected based on certain characteristic patterns in the profile of the phase currents (so-called “inrush detection”), and the generation of a fault signal is blocked in the case of the existence of an activation operation. A further method for detecting the existence of an activation operation is known, for example, from the IEEE publication “A new method to identify inrush current based on error estimation”, He B., Zhang X., Bo Z., IEEE Transactions on Power Delivery, Volume 21, No. 3, July 2006, pp. 1163-1168. A method based on the use of fuzzy logic for detecting different system states is also known from the IEEE publication “A self-organizing fuzzy logic based protective relay—an application to power transformer protection”, Kasztenny, B., Rosolowski, E, Saha, M. M., Hillstrom, B., IEEE Transactions on Power Delivery, Volume 12, No. 3, July 1997, pp. 119-1127.

By adding ever-more operating states in which the generation of a fault signal is to be blocked, and corresponding additional algorithms, both the complexity of a differential protection device used for carrying out the corresponding algorithms and the number of parameters to be set by an operator of such a differential protection device necessarily increase. The probability of malfunctions and/or incorrect settings also increases with increasing complexity and the number of parameters, causing the functionality of the differential protection device to be impaired overall.

In the case of the differential protection of generators, no additional algorithms have generally been used until now for stabilizing against activation operations. Although additional stabilization is used for detecting external faults, the short-circuit currents are often so small that under certain circumstances, for example, in the case of so-called “near-generator faults”, the risk of incorrect decisions may exist.

It is therefore an object of the present invention to provide a differential protection method via which a reliable generation of a fault signal may be ensured with comparatively low complexity, only in the case of faults which actually exist in the area of the electrical component. The object of the present invention is also to provide a correspondingly designed differential protection device.

With respect to the differential protection method, this object is achieved via a differential protection method of the kind initially specified, in which the stabilization current values in a predefined observation time period are compared with the associated differential current values in each case, and on the basis of the comparison, a fault indicator is formed which indicates whether the proportion of the differential current values or the proportion of the stabilization current values predominates, and the generation of the fault signal is blocked if the fault indicator indicates a predominant proportion of the stabilization current values.

The particular advantage of the method according to the present invention is that by considering a single criterion, it is possible to reliably detect such operating states of the electrical power supply system in which the generation of a fault signal is to be blocked, since they do not indicate the actual presence of a fault. As a result of the decision being made based on a fault indicator which is not formed selectively through the use of a single measurement value pair, but rather includes, as it were, the temporal “prehistory” of the current measurement value pair because of the observation time period used, a highly reliable differentiation may be made between faults actually lying in the area of the component (“internal faults”) and other operating states which require no generation of a fault signal. During the formation of a fault indicator, it is simultaneously analyzed whether a proportion of the differential current values or a proportion of the stabilization current values predominates during the observation time period. The first indicates the existence of an internal fault, while the latter indicates the existence of another operating state in which the generation of a fault signal is to be blocked.

The differential protection method according to the present invention may, for example, be used for monitoring transformers. In addition, it may advantageously also be used for monitoring electric machines (generators). In this case, the method has proven to be reliable in particular in the case of so-called “near-generator external faults” having comparatively low fault currents and long time constants of the direct-current component.

In the case of transformer protection as well as generator protection, the method according to the present invention also allows a reliable distinction to be made between external faults with the occurrence of transformer saturation, or activation operations on the one hand and internal faults on the other hand.

One advantageous refinement of the method according to the present invention provides that for the formation of the fault indicator, the integral mean value is determined from differences formed through the use of the differential current values and the stabilization current values.

According to this specific embodiment of the method according to the present invention, the differential current values and the associated stabilization current values in each case are initially used to form a difference which allows a conclusion to be drawn about the predominant proportion. This difference formation is carried out over the entire observation time period, and the integral mean value of all differences is formed in order to determine the fault indicator.

According to a further advantageous specific embodiment of the method according to the present invention, it may also be provided that a transformer or a generator is used as an electrical component.

In this connection, it may also be provided that the fault indicator is determined differently as a function of the type of electrical component.

For example, different weighting factors for the differential current values or the stabilization current values may be used for different types of electrical components during the formation of the fault indicator.

A decision about blocking the generation of the fault signal may be made in a particularly simple manner in that the fault indicator is compared with a predefined threshold value, and the generation of the fault signal is blocked if the fault indicator falls below the threshold value.

In this connection, according to a further advantageous specific embodiment of the method according to the present invention, it may be provided that the threshold value is determined differently as a function of the type of electrical component.

According to a further advantageous specific embodiment of the method according to the present invention, it may also be provided that the fault indicator is determined through the direct use of the differential current values or through the use of values derived from the differential current values.

In the case of direct use of the differential current values, they are directly compared with the associated stabilization current values, for example, via difference formation. In the case of using values which are derived from the differential current values, for example, a respective first derivative of the differential current values multiplied by the angular frequency co of the profile of the current measurement values may initially be used for comparison with the stabilization current values.

Specifically, according to a further advantageous specific embodiment of the method according to the present invention, it may be provided that the fault indicator is formed as follows:

$$J ( t ) = \frac{1}{{T}_{1}} \cdot {\int }_{t - {T}_{1 }}^{t} ( {i}_{op} - K \cdot {i}_{r} ) d t$$

where
J(t): fault indicator;
t: time;
T₁: length of the predefined observation time period;
iₒₚ: triggering current formed from the differential current values;
K: adjustment factor for adjusting to the type of electrical component;
iᵣ: stabilization current.

As is readily apparent, the term within the integral describes the comparison made by forming the difference between a triggering current based on the differential current values and the respective stabilization current values, weighted by a component-dependent adjustment factor. The observation time period T₁ may, for example, be chosen to be 20 ms (one period). In the case of a transformer as a component, the adjustment factor K may, for example, assume the value 0.3, and in the case of a generator as a component, it may assume the value 0.7.

In the case of a multiphase (for example, three-phase) electrical component, it is also considered to be advantageous if the fault indicator is determined for each phase of a multiphase electrical component, and the generation of the fault signal is then blocked only if the fault indicators for all phases fall below the predefined threshold value.

As a result, it may be ensured that the generation of a fault signal is then blocked only if a faulty state may be ruled out equally for all phases via the fault indicator.

The aforementioned object is also achieved via a differential protection device of the kind initially specified, in which the analysis device is also configured to compare the stabilization current values in a predefined observation time period with the associated differential current values in each case, and based on the comparison, to form a fault indicator which indicates whether the proportion of the differential current values or the proportion of the stabilization current values predominates, and to block the generation of the fault signal if the fault indicator indicates a predominant proportion of the stabilization current values.

In connection with the differential protection device, it may also be provided that the analysis device is configured to determine the integral mean value from differences formed through the use of the differential current values and the stabilization current values for the formation of the fault indicator.

In addition, according to a further advantageous specific embodiment of the differential protection device according to the present invention, it may be provided that the analysis device is configured to compare the fault indicator with a predefined threshold value, and to block the generation of the fault signal if the fault indicator falls below the threshold value.

With respect to the differential protection device according to the present invention, all embodiments made above and below for the differential protection method according to the present invention are valid and vice versa; in particular, the differential protection device according to the present invention is configured for carrying out the differential protection method according to the present invention in any specific embodiment or a combination of any specific embodiments. Reference is also made to the advantages described for the differential protection method according to the present invention with respect to the advantages of the differential protection device according to the present invention.

The present invention is described in greater detail below based on an exemplary embodiment. The specific design of the exemplary embodiment is in no way to be understood as limiting for the general design of the differential protection method according to the present invention and the differential protection device according to the present invention; rather, individual design features of the exemplary embodiment may be combined freely with each other and with the above-described features in any manner.

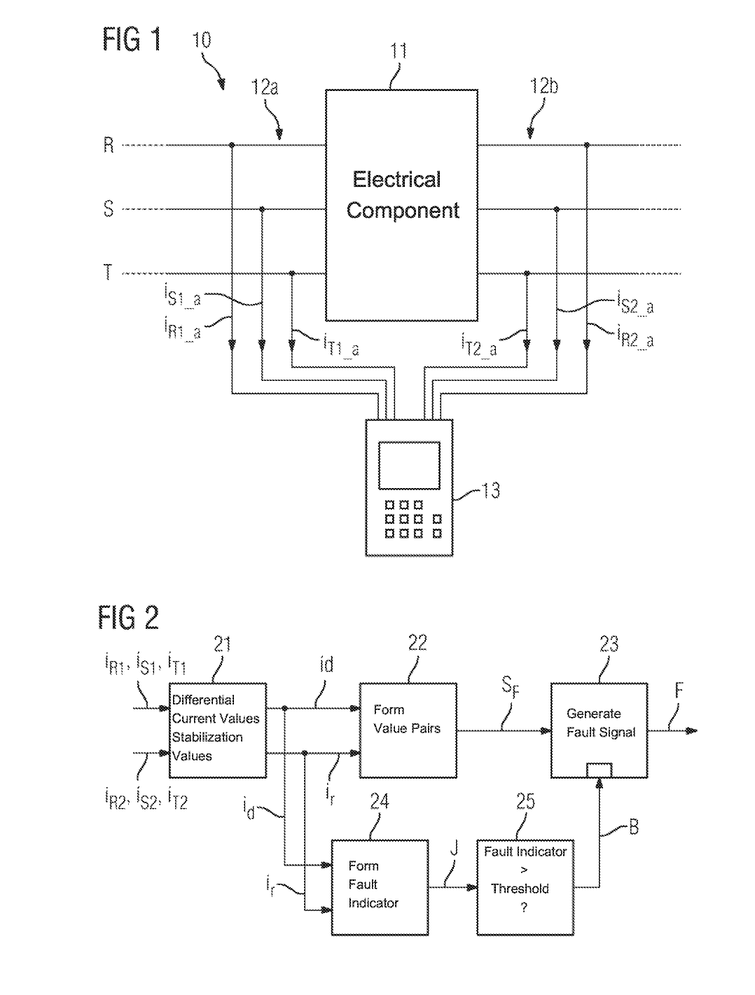

FIG. 1 shows a schematic view of a component of an electrical power supply system monitored via a differential protection device;

FIG. 2 shows a flow diagram for explaining an exemplary embodiment of a differential protection method;

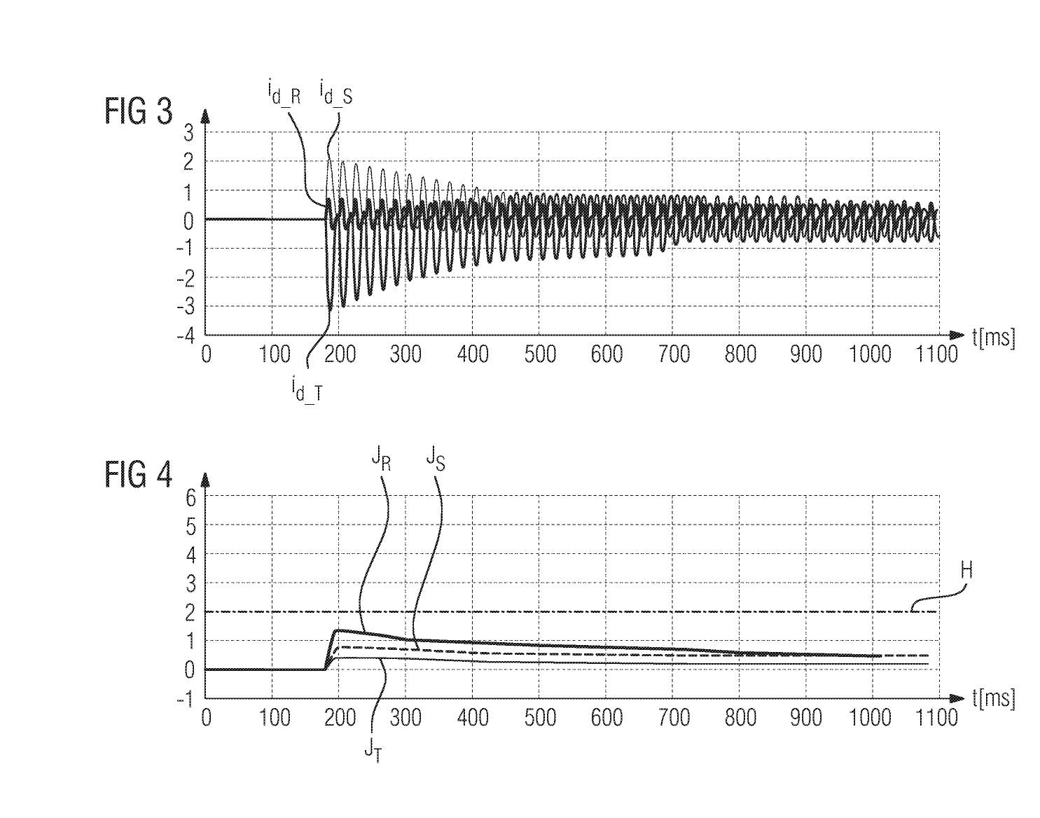

FIGS. 3 to 4 show diagrams for explaining a first exemplary embodiment of the analysis of current measurement values via a differential protection method;

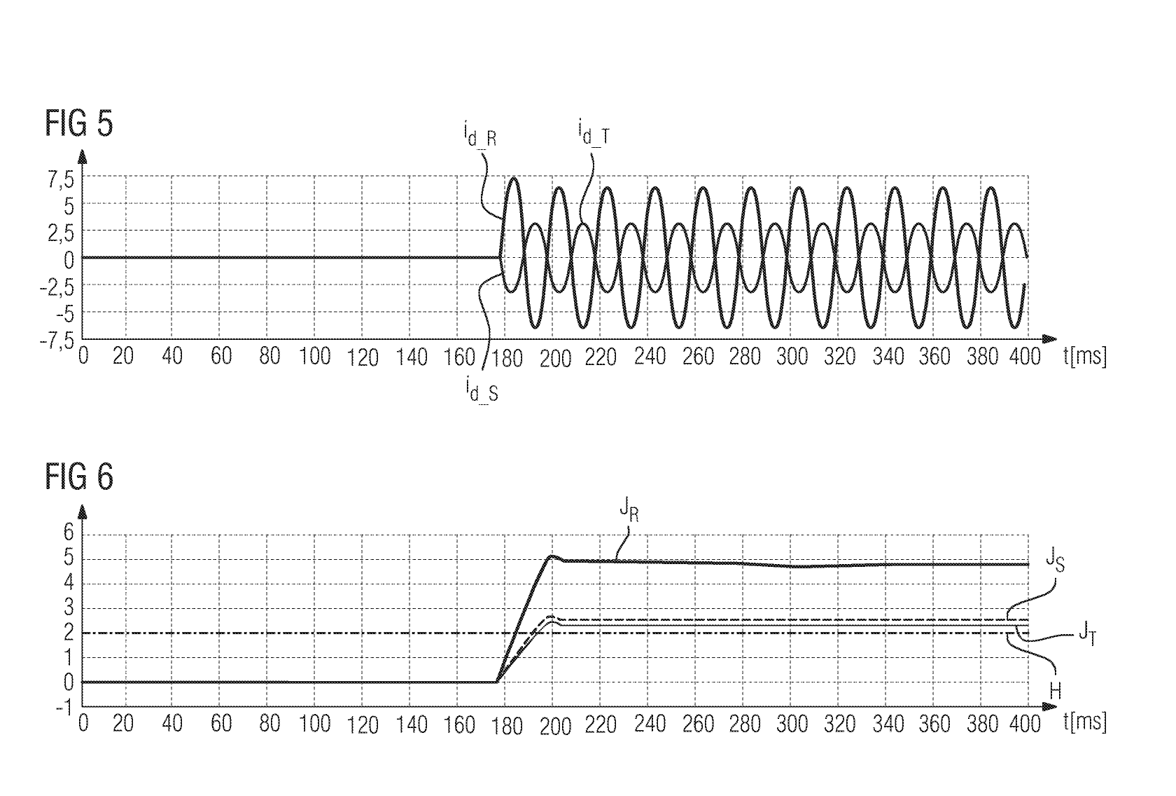

FIGS. 5 to 6 show diagrams for explaining a second exemplary embodiment of the analysis of current measurement values via a differential protection method;

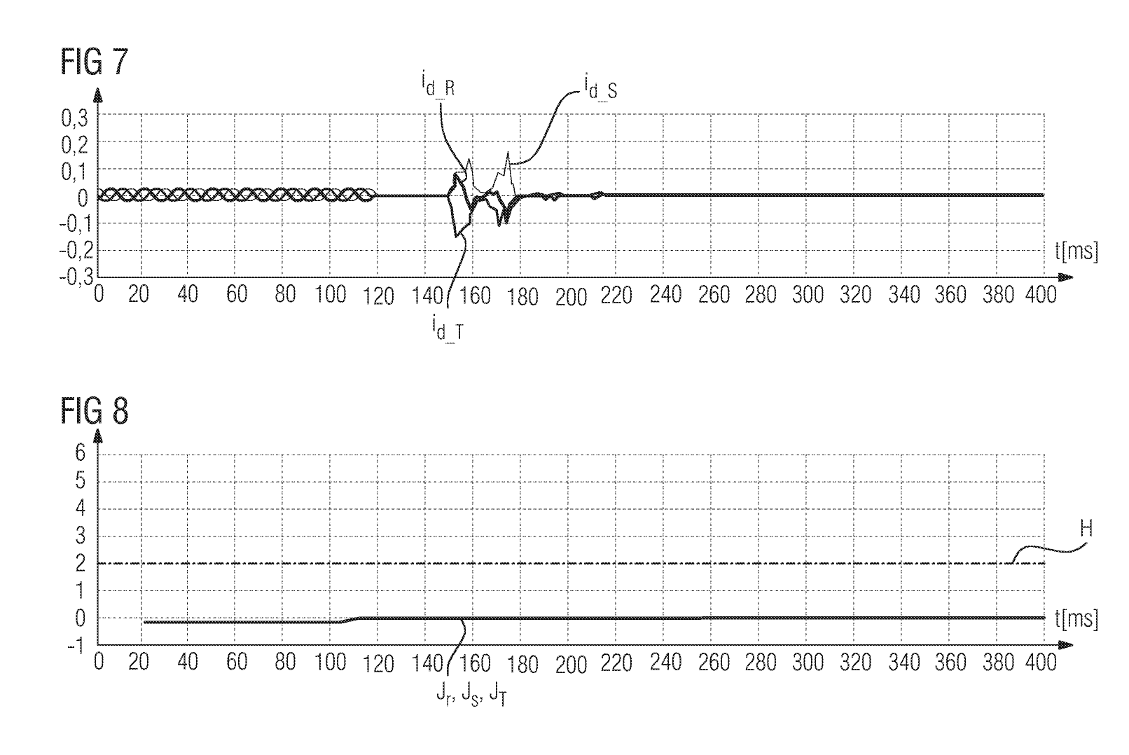

FIGS. 7 to 8 show diagrams for explaining a third exemplary embodiment of the analysis of current measurement values via a differential protection method; and

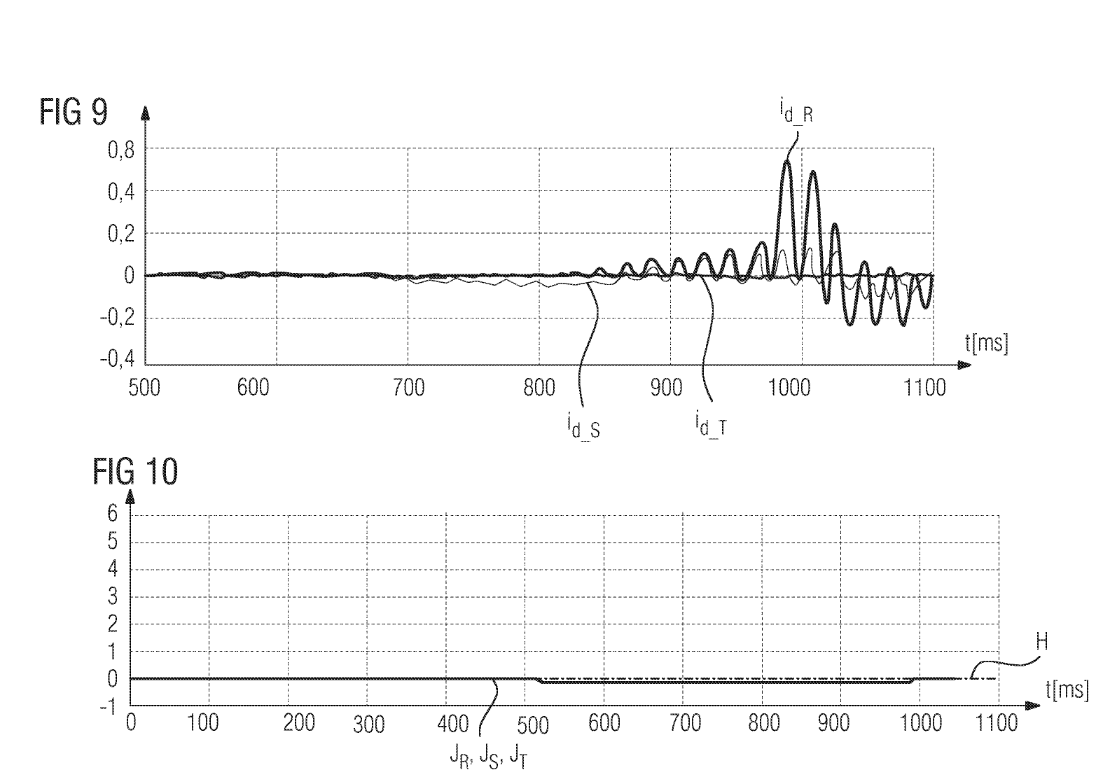

FIGS. 9 to 10 show diagrams for explaining a fourth exemplary embodiment of the analysis of current measurement values via a differential protection method.

In FIG. 1, a section 10 of an electrical power supply system, which is not depicted further, is apparent. The section 10 has an electrical component 11 which, for example, may be a transformer or a generator. The component 11 is monitored for faults, for example, short circuits, by means of a differential protection method described in greater detail below.

For this purpose, for the individual phase conductors R, S, T, similar instantaneous values of the phase currents i_{R1}_{_}ₐ, i_{S1}_{_}ₐ, i_{T1}_{_}ₐ are detected at a first measurement location 12a, and phase currents i_{R2}_{_}ₐ, i_{S2}_{_}ₐ, i_{T2}_{_}ₐ are detected at a second measurement location 12b, and are supplied to a differential protection device 13. The differential protection device has a measurement value detection device (not shown in FIG. 1), via which the phase currents are detected and converted via sampling into corresponding current measurement values i_{R1}, i_{S1}, i_{T1} or i_{R2}, i_{S2}, i_{T2}. In deviation from the depiction according to FIG. 1, the sampling may in this case also be carried out by means of the current converters used for detecting the current or a sampling device downstream from it; in this case, the sampled current measurement values i_{R1}, i_{S1}, i_{T1} or i_{R2}, i_{S2}, i_{T2} would already be transmitted directly to the differential protection device 13.

The differential protection device 13 is equipped with an analysis device (also not shown in FIG. 1), to which the individual current measurement values i_{R1}, i_{S1}, i_{T1} or i_{R2}, i_{S2}, i_{T2} are supplied. The analysis device analyzes the current sampled values i_{R1}, i_{S1}, i_{T1} or i_{R2}, i_{S2}, i_{T2} through the use of a differential protection method and generates a fault signal F if an internal fault, i.e., a fault in the area of the component 11, has been detected. The fault signal F may, for example, be used to generate a triggering signal for a switching device, for example, a power switch, via which the faulty component is disconnected from the rest of the electrical power supply system.

In order to increase the reliability of the fault detection, the analysis device of the differential protection device 13 also checks whether certain operating states of the electrical power supply system, for example, an activation operation, exist, which may influence the carrying out of the differential protection method in such a way that the fault signal F could also be generated if no fault actually exists in the area of the component 11. If such an operating state of the electrical power supply system is detected, the generation of the fault signal F is blocked in order to avoid an erroneous triggering of the differential protection device 13.

In FIG. 2, a flow diagram is shown by way of example which shows an exemplary embodiment of the functioning of the differential protection device 13 according to FIG. 1. In this case, the flow chart is depicted in the form of a block diagram; however, the implementation of the described differential protection method may be carried out both in the form of software and hardware, as well as a combination of the two.

Initially, the current measurement values i_{R1}, i_{S1}, i_{T1} or i_{R2}, i_{S2}, i_{T2} are supplied to a first analysis step 21. If the electrical component 11 is a transformer, in a preceding step, the current measurement values of both voltage sides of the transformer must be adjusted to each other. For this purpose, a voltage level adjustment, a switching group adjustment, and possibly a zero-voltage correction or elimination are carried out in a manner known to those skilled in the art. In the following equations, all values are calculated in relation to the nominal current of the component (unit: p.u.) and at consecutive sampling points n.

In the first analysis step 21, differential current values i_{d} and stabilization current values iᵣ are formed from the current measurement values as described below. The formation is in turn carried out by phase; however, the following exemplary embodiment is depicted for only one phase for the sake of simplicity.

The differential current values i_{d} of each phase R, S, T are calculated according to equation (1):

i_{d}=i₁−i₂. (1)

In this case, as already mentioned, the respective phase-related current measurement values i_{R1}, i_{S1}, i_{T1} or i_{R2}, i_{S2}, i_{T2} are to be used for the phase-wise calculation, instead of i₁ and i₂.

The stabilization current values iᵣ are determined according to equation (2) as follows:

iᵣ=max[|iᵣ₁|;|iᵣ₂|], (2)

In this case, iᵣ₁ and iᵣ₂ represent the stabilization currents at the respective measurement locations 12a or 12b. They are, for example, determined according to the following equations (3a) and (3b):

$$\begin{matrix}{i}_{r 1} = max [ \vert {i}_{1} \vert ; \frac{1}{ω} \vert {i}_{1}^{′} \vert ] , & ( 3 a ) \\ {i}_{r 2} = max [ \vert {i}_{2} \vert ; \frac{1}{ω} \vert {i}_{2}^{′} \vert ] , & ( 3 b )\end{matrix}$$

In this case, the respective phase-related current measurement values i_{R1}, i_{S1}, i_{T1} or i_{R2}, i_{S2}, i_{T2} are again to be used for the phase-wise calculation, instead of i₁ and i₂. In addition, i₁′ and i₂′ represent the respective first derivative of the current measurement values, and ω represents the angular frequency of the current. The first derivatives may be determined, for example, through the use of a difference quotient (shown here by way of example for i₁′):

$${i}_{1}^{′} = \frac{1}{{T}_{s}} ( {i}_{1} ( n ) - {i}_{1} ( n - 1 ) ) . \qquad ( 4 )$$

In this case, Tₛ represents the sampling period. In a next analysis step 22, value pairs are formed in each case from a differential current value and an associated stabilization current value, i.e., one formed from simultaneously ascertained current measurement values, and checked with respect to their position in a triggering diagram. If the value pair lies within a triggering range, this is rated as an indication of an internal fault, and a corresponding indication signal S_{F} is passed to a following analysis step 23. The following analysis step 23 is used for the generation of the fault signal if the indication signal S_{F} exists.

The differential current values and stabilization current values formed in the analysis step 21 are also supplied to an analysis step 24, which uses them to form a fault indicator via which it may be checked whether a proportion of the differential current values or a proportion of the stabilization current values predominated in a previous observation time period T₁. The fault indicator may, for example, be ascertained as depicted in equation (5):

$$J ( t ) = \frac{1}{{T}_{1}} \cdot {\int }_{t - {T}_{1 }}^{t} ( {i}_{op} - K \cdot {i}_{r} ) d t$$

where
J(t): fault indicator;
t: time;
T₁: length of the predefined observation time period;
iₒₚ: triggering current formed from the differential current values;
K: adjustment factor for adjusting to the type of electrical component;
iᵣ: stabilization current.

In this equation, the triggering current iₒₚ is ascertained directly or indirectly from the differential current values and may, for example, be formed as specified in equation (6):

$${i}_{op} = max [ \vert {i}_{d} \vert ; \frac{1}{ω} \vert {i}_{d}^{′} \vert ] .$$

In this case, a difference quotient may again be used for the formation of the first derivative i_{d}′, similarly to the approach according to equation (4).

The adjustment factor K is used for adjusting the formation of the fault indicator J to the type of electrical component and may, for example, assume the value 0.3 in the case of a transformer and the value 0.7 in the case of a generator. It is used for weighting the stabilization current values for the comparison with the differential current values or the triggering current formed from them. The exact value of the adjustment factor may, for example, also be ascertained via experiments or simulations.

In a following analysis step 25, the fault indicator J is compared with a threshold value H. The threshold value H may also be determined as a function of the type of electrical component; for example, it may assume the value 2.0 in the case of a transformer and the value 0.0 in the case of a generator. The exact value of the threshold value may, for example, also be ascertained via experiments or simulations.

The fault indicator J is formed individually for each phase and compared with the threshold value H. In the analysis step 25, exactly one blocking signal B is then generated if the fault indicators of all three phases fall below the threshold value H. The blocking signal B is supplied to the analysis step 23. In the case of a pending blocking signal B, the generation of the fault signal F is prevented in the analysis step 23.

In the following figures, the behavior of the described differential protection method is depicted for different scenarios based on diagrams with exemplary profiles of differential current values and the corresponding fault indicator in each case.

FIGS. 3 and 4 relate to a first scenario, in which an activation operation exists in the electrical power supply system. The monitored component is a transformer. In FIG. 3, the profile of the differential current values for the individual phases is depicted, while FIG. 4 shows the profile of the fault indicator for each individual phase. It is clearly apparent in the diagram in FIG. 3 that after approximately 700 ms, the current converters go into saturation due to a direct current component. Without further stabilization, the comparatively high differential current due to the activation operation and the transformer saturation would result in the generation of a fault signal F. However, as a result of the additional analysis of the fault indicator J, it may be achieved that the generation of the fault signal F is blocked, since the fault indicator lies permanently below the threshold value H having the value 2.0 (for transformers).

FIGS. 5 and 6 relate to a second scenario in which an internal fault exists in the component 11. The monitored component is a transformer. In FIG. 5, the profile of the differential current values for the individual phases is depicted, while FIG. 6 shows the profile of the fault indicator for each individual phase. The comparatively high differential current, in combination with the fault indicator J lying above the threshold value H having the value 2.0, results in a reliable generation of the fault signal F.

FIGS. 7 and 8 relate to a third scenario, in which an external fault (a fault outside the component) exists. The monitored component is a transformer. In FIG. 7, the profile of the differential current values for the individual phases is depicted, while FIG. 8 shows the profile of the fault indicator for each individual phase. It is clearly apparent in the diagram in FIG. 7 that current transformer saturation occurs approximately 60 ms after the occurrence of a fault. Without further stabilization, the comparatively high differential current due to the transformer saturation would result in the generation of a fault signal F. However, as a result of the additional analysis of the fault indicator J, it may be achieved that the generation of the fault signal F is blocked, since the fault indicator lies permanently below the threshold value H having the value 2.0 (for transformers).

Finally, FIGS. 9 and 10 relate to a fourth scenario, in which a near-generator external fault exists having a low conductor current. The monitored component is a generator. In FIG. 9, the profile of the differential current values for the individual phases is depicted, while FIG. 10 shows the profile of the fault indicator for each individual phase. Transformer saturation again occurs due to existing direct-current components. Without further stabilization, the comparatively high differential current would result in the generation of a fault signal F. However, as a result of the additional analysis of the fault indicator J, it may be achieved that the generation of the fault signal F is blocked, since at no point in time do the fault indicators of all three phases lie above the threshold value H having the value 0.0 (for generators).

1-12. (canceled)

13. A differential protection method for generating a fault signal which indicates a fault occurring at an electrical component of an electrical power supply system, the method comprising:
measuring current measurement values at each of at least two different measurement locations of the component, and forming differential current values and stabilization current values from the current measurement values;
comparing the stabilization current values within a predefined observation time period with associated differential current values in each case and, based on a comparison result, forming a fault indicator that indicates whether a proportion of the differential current values or a proportion of the stabilization current values dominates; and
performing a triggering range test and, if the triggering range test indicates that a measurement value pair formed from one of the differential current values and the associated stabilization value in each case lies in a predefined triggering range, generating the fault signal; and
blocking the generation of the fault signal if the fault indicator indicates a predominant proportion of the stabilization current values.

14. The differential protection method according to claim 13, which comprises, for forming the fault indicator, determining an integral mean value from differences formed through the use of the differential current values and the stabilization current values.

15. The differential protection method according to claim 13, wherein the electrical component is a transformer or a generator.

16. The differential protection method according to claim 15, which comprises determining the fault indicator differently in dependence on a type of the electrical component.

17. The differential protection method according to claim 13, which comprises:
comparing the fault indicator with a predefined threshold value; and
blocking the generation of the fault signal if the fault indicator falls below the threshold value.

18. The differential protection method according to claim 17, which comprises determining the threshold value differently in dependence on a type of the electrical component.

19. The differential protection method according to claim 13, which comprises determining the fault indicator through a direct use of the differential current values or through a use of values derived from the differential current values.

20. The differential protection method according to claim 13, wherein the step of forming the fault indicator comprises carrying out the following calculation:
$$J ( t ) = \frac{1}{{T}_{1}} \cdot {\int }_{t - {T}_{1 }}^{t} ( {i}_{op} - K \cdot {i}_{r} ) d t$$
where
J(t): fault indicator;
t: time;
T₁: predefined observation time period;
iₒₚ: triggering current formed from the differential current values;
K: adjustment factor for adjusting to the type of electrical component;
iᵣ: stabilization current.

21. The differential protection method according to claim 13, which comprises:
determining the fault indicator for each phase of a multiphase electrical component; and
blocking the generation of the fault signal only if the fault indicators for all phases fall below the predefined threshold value.

22. A differential protection device, comprising:
a measurement value detection device for detecting current measurement values determined at different locations at an electrical component of an electrical power supply system; and
an analysis device connected to said measurement value detection device, said analysis device being configured:
for forming differential current values and stabilization values from the current measurement values;
for generating a fault signal if a triggering range test indicates that a measurement value pair formed from one of the differential current values and the associated stabilization value in each case lies in a predefined triggering range;
for comparing the stabilization current values in a predefined observation time period with the associated differential current values in each case and, based on a result of the comparison, to form a fault indicator which indicates whether the proportion of the differential current values or the proportion of the stabilization current values predominates; and
for blocking a generation of the fault signal if the fault indicator indicates a predominant proportion of the stabilization current values.

23. The differential protection device according to claim 22, wherein said analysis device is configured to determine an integral mean value from differences formed by using the differential current values and the stabilization current values for the formation of the fault indicator.

24. The differential protection device according to claim 22, wherein:
said analysis device is configured to compare the fault indicator with a predefined threshold value; and
to block the generation of the fault signal if the fault indicator falls below the threshold value.
